(19) United States
(12) Patent Application Publication
(10) Pub. No.: US 2015/0252476 A1
(43) Pub. Date: Sep. 10, 2015

(54) SUBSTRATE PROCESSING APPARATUS

(71) Applicant: EUGENE TECHNOLOGY CO., LTD., Yongin-si, Gyeonggi-do (KR)

(72) Inventors: Il-Kwang Yang, Gyeonggi-do (KR); Byoung-Gyu Song, Gyeonggi-do (KR); Kyong-Hun Kim, Gyeonggi-do (KR); Yong-Ki Kim, Chungcheongnam-do (KR); Yang-Sik Shin, Gyeonggi-do (KR)

(73) Assignee: EUGENE TECHNOLOGY CO., LTD., Yongin-si, Gyeonggi-do (KR)

(21) Appl. No.: 14/427,333

(22) PCT Filed: Sep. 17, 2013
(86) PCT No.: PCT/KR2013/008433

§ 371 Date: Mar. 11, 2015

(30) Foreign Application Priority Data
Sep. 17, 2012 (KR) 10-2012-0102925

(51) Int. Cl. C23C 16/458; C23C 16/46

(52) U.S. Cl. CPC C23C 16/4586; C23C 16/46

(57) ABSTRACT

Provided is a substrate processing apparatus. The substrate processing apparatus in which a process with respect to a substrate is performed includes a main chamber having an opened upper portion, the main chamber having a passage that is defined in a sidewall thereof so that a substrate is accessible, a chamber cover disposed on the opened upper portion of the main chamber to provide a process space, which is sealed from the outside, in which the process is performed, a susceptor plate on which the substrate is placed, the susceptor plate having an inner space with an opened lower portion, and a main heater rotatably disposed in the inner space, the main heater being spaced apart from the susceptor plate to heat the susceptor plate.

### TECHNICAL FIELD

The present invention disclosed herein relates to an apparatus for processing a substrate, and more particularly, to a substrate processing apparatus which improves a process temperature distribution within a substrate by using a susceptor plate disposed above a heater.

### BACKGROUND ART

Uniform heat treatment of a substrate at a high temperature is required in a semiconductor device manufacturing process. Examples of the semiconductor device manufacturing process may include chemical vapor deposition and silicon epitaxial growth processes in which a material layer is deposited on a semiconductor substrate placed on a susceptor within a reactor in a gaseous state. The susceptor may be heated at a high temperature ranging from about 400° C. to about 1,250° C. by resistance heating, radio-frequency heating, and infrared heating. Also, a gas may pass through the reactor, and thus a deposition process may occur very close to a surface of the substrate by chemical reaction of the gas in a gaseous state. A desired product may be deposited on the substrate due to this reaction.

A semiconductor device includes a plurality of layers on a silicon substrate. The layers are deposited on the substrate through a deposition process. The deposition process has several important issues that are important to evaluate the deposited layers and select a deposition method.

First, one example of the important issues is ‘quality’ of each of the deposited layers. The ‘quality’ represents composition, contamination levels, defect density, and mechanical and electrical properties. The composition of the deposited layer may be changed according to deposition conditions. This is very important to obtain a specific composition.

Second, another example of the issues is a uniform thickness over the wafer. Specifically, a thickness of a layer deposited on a pattern having a nonplanar shape with a stepped portion is very important. Here, whether the thickness of the deposited film is uniform may be determined through a step coverage which is defined as a ratio of a minimum thickness of the film deposited on the stepped portion divided by a thickness of the film deposited on the pattern.

The other issue with respect to the deposition may be a filling space. This represents a gap filling in which an insulating layer including an oxide layer is filled between metal lines. A gap is provided to physically and electrically isolate the metal lines from each other. Among the issues, uniformity is one of very important issues with respect to the deposition process. A non-uniform layer may cause high electrical resistance on the metal lines to increase possibility of mechanical damage.

### DISCLOSURE

### Technical Problem

The present invention provides a substrate processing substrate in which a susceptor plate is disposed above a heater to indirectly heat the substrate, improving temperature gradient of the substrate.

The present invention also provide a substrate processing apparatus in which an upper heater is disposed on an upper portion of a chamber cover to preliminarily heat a process gas, thereby reducing a process reaction time.

Further another object of the present invention will become evident with reference to following detailed descriptions and accompanying drawings.

### Technical Solution

Embodiments of the present invention provide substrate processing apparatuses in which a process with respect to a substrate is performed, the substrate processing apparatuses including: a main chamber having an opened upper portion, the main chamber having a passage that is defined in a sidewall thereof so that a substrate is accessible; a chamber cover disposed on the opened upper portion of the main chamber to provide a process space, which is sealed from the outside, in which the process is performed; a susceptor plate on which the substrate is placed, the susceptor plate having an inner space with an opened lower portion; and a main heater rotatably disposed in the inner space, the main heater being spaced apart from the susceptor plate to heat the susceptor plate.

In some embodiments, the substrate processing apparatuses may further include a support member disposed on the opened lower portion of the susceptor plate to prevent heat within the inner space from being diffused into the outside.

In other embodiments, the substrate processing apparatuses may further include a rotation shaft disposed on a lower portion of the main heater to support the main heater, the rotation shaft being rotatable together with the main heater, wherein the main heater may include: a heating plate disposed on an upper portion of the rotation shaft, the heating plate being inserted into the inner space; and a heating wire disposed in the heating plate to heat the susceptor plate.

In still other embodiments, the main chamber may have an opened lower portion, and the substrate processing apparatuses may further include a pumping block disposed on the opened lower portion of the main chamber to provide an inner installation space, the pumping block being disposed along a circumference of the rotation shaft.

In even other embodiments, the main heater and the rotation shaft may be disposed in the inner installation space, and the substrate processing apparatuses may include: a plurality of holders supporting the substrate placed thereon, the holders being movable between an ascending position and a descending position; an elevation shaft connected to the holders to elevate the holders; a discharge hole defined in the pumping block along the circumference of the rotation shaft to discharge a process gas to the outside; and an elevation hole in which the elevation shaft is inserted, the elevation hole being defined outside the discharge hole.

In yet other embodiments, the substrate processing apparatuses may further include: a gas supply hole defined in a top surface of the chamber cover to supply the process gas into a process space; a diffusion plate disposed on a lower end of the chamber cover, the diffusion plate having diffusion holes through which the process gas is diffused onto the substrate; and an upper heater disposed on an upper portion of the chamber cover to preliminarily heat the process gas to be supplied into the process space.

In further embodiments, the substrate processing apparatuses may further include an elevation unit elevating the substrate, wherein the elevation unit may include: a plurality of holders supporting the substrate placed thereon, the holders being movable between an ascending position and a descending position; and an elevation shaft connected to the holders to elevate the holders.

In still further embodiments, the susceptor plate may have an elevation groove defined along an edge of a top surface thereof, and each of the holders may have a top surface having a height greater than that of a top surface of the susceptor plate at the ascending position and be inserted into the elevation groove and spaced apart from a bottom surface of the substrate at the descending position.

In even further embodiments, the chamber cover may have an upper portion with a dome shape that protrudes upward or a flat plate shape.

### Advantageous Effects

According to the embodiment of the present invention, the susceptor plate may be disposed above the heater to indirectly heat the substrate, improving the temperature gradient of the substrate. Also, the upper heater may be disposed on the upper portion of the chamber cover to preliminarily heat the process gas, thereby reducing the process reaction time.

### DESCRIPTION OF DRAWINGS

FIG. 1 is a schematic view of a substrate processing apparatus according to an embodiment of the present invention;

FIGS. 2 and 3 are views illustrating a moving operation of an elevation unit of FIG. 1;

FIG. 4 is a cross-sectional view illustrating an arrangement state of a holder of FIG. 1;

FIG. 5 is a schematic view of a substrate processing apparatus according to a first modified example of the present invention; and

FIG. 6 is a schematic view of a substrate processing apparatus according to a second modified example of the present invention.

### BEST MODE

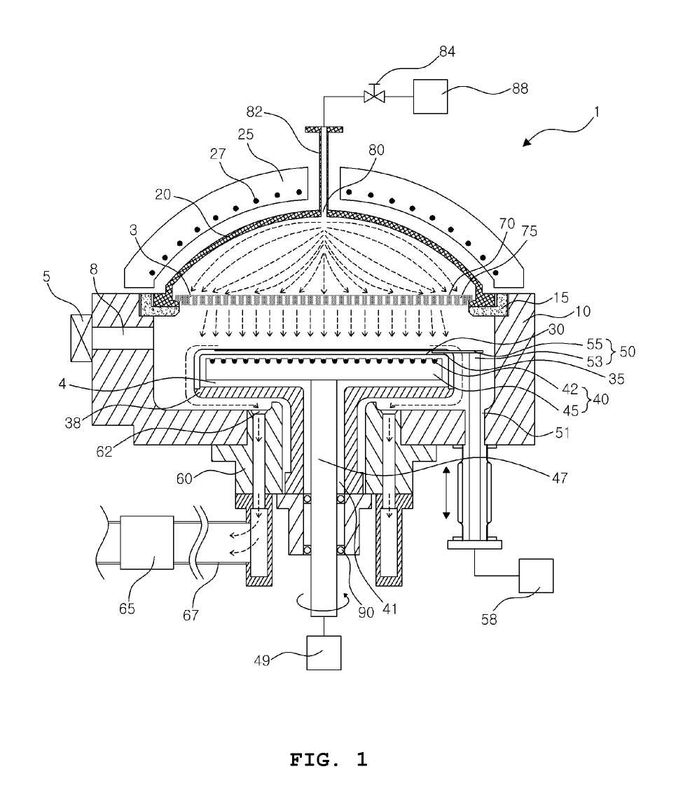

Hereinafter, exemplary embodiments of the present invention will be described in detail with reference to FIGS. 1 to 4. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the shapes of components are exaggerated for clarity of illustration.

Although a deposition process is described below as an example, the present invention may be applicable to various substrate processing processes including the deposition process. Also, it is obvious to a person skilled in the art that the present invention is applicable to various objects to be processed in addition to a substrate W described in the embodiments.

FIG. 1 is a schematic view of a substrate processing apparatus according to an embodiment of the present invention. Referring to FIG. 1, a substrate processing apparatus 1 includes a main chamber 10 and a chamber cover 20. The main chamber 10 has an opened upper side. Also, a passage 8 through which a substrate W is accessible is defined in a side of the main chamber 10. The substrate W may be loaded into or unloaded from the main chamber 10 through the passage 8 defined in the side of the main chamber 10. A gate valve 5 is disposed outside the passage 8. The passage 8 may be opened or closed by the gate valve 5.

The chamber cover 20 is connected to the opened upper side of the main chamber 10 to define a process space blocked from the outside. A connection member 15 may be disposed between the main chamber 10 and the chamber cover 20 to completely seal the process space 3. A gas supply hole 80 passes through a ceiling wall of the chamber cover 20. Thus, a process gas is supplied into the main chamber 10 through the gas supply hole 80. The gas supply hole 80 is connected to a process gas storage tank 88 through a process gas port 82, and a valve 84 can adjust a process gas inflow rate.

A diffusion plate 70 having a plurality of diffusion hole 75 is disposed on a lower end surface of the chamber cover 20. The diffusion plate 70 may uniformly supply the process gas onto a substrate W through the plurality of diffusion holes 75 defined at the same height. The process gas may include hydrogen (H₂), nitrogen (N₂), or the other inert gas. Also, the process gas may include a precursor gas such as silane (SiH₄) or dichlorosilane (SiH₂Cl₂). Also, the process gas may include a dopant source gas such as diborane B₂H₆) or phosphine (PH₃). The diffusion plate 70 diffuses the process gas supplied through the gas supply hole 80 onto the substrate W.

An upper heater 25 heating the process gas introduced through the gas supply hole 80 is disposed on an upper portion of the chamber cover 20. The chamber cover 20 may have a dome shape that protrudes upward. Also, the upper heater 25 may have a shape corresponding to that of the chamber cover 20. Heating wires 27 disposed within the upper heater 25 may be disposed spaced a preset distance from each other along a top surface of the chamber cover 20. The heating wires 27 apply heat to the chamber cover 20 to preliminarily heat the process gas supplied from the gas supply hole 80. The preliminarily heated process gas may be diffused onto the substrate W through the diffusion plate 70 to perform a substrate processing process. Thus, since the primarily preliminary-heated process gas is supplied onto the substrate W, a process reaction time between the process gas and the substrate W may be reduced to increase productivity.

A main heater 40 is disposed within the main chamber 10. A susceptor plate 30 spaced apart from the main heater 40 is disposed above the main heater 40. The susceptor plate 30 has an inner space 4 with an opened lower portion. A support member 38 is disposed on the opened lower portion of the susceptor plate 30 to prevent heat of the main heater 40 from being diffused into the outside of the inner space 4. A through hole 41 is defined in a lower side of a central portion of the main chamber 10. A rotation shaft 47 is inserted into the through hole 41. The rotation shaft 47 is connected to a lower portion of the main heater 40 to support the main heater 40. The rotation shaft 47 is connected to a driving part 49 to rotate together with the main heater 40.

The main heater 40 includes a heating plate 45 and heating wires 42. The heating plate 45 is disposed on an upper portion of the rotation shaft 47 and inserted into the inner space 4 of the susceptor 30. The heating wires 42 may be disposed in a top surface of the heating plate 45. That is, the main heater 40 heats the susceptor plate 30 spaced upward therefrom, and the susceptor plate 30 transfers the heat received from the main heater 40 into the substrate W. The inner space 4 heating the susceptor plate 30 may be isolated from the process space 3 by the susceptor plate 30 and the support member 38. Also, a bearing 90 may be disposed on a lower portion of the rotation shaft 47.

In recent years, as a large-scaled substrate W having a size of about 300 mm (about 12 inches) to about 450 mm (about 18 inches) is manufactured, the heater is increasing in size. Thus, it may be difficult to realize uniform temperature distribution on a substrate. That is, while the substrate W is heated at a process temperature, the present invention adopts an indirect heating method using the susceptor plate, but does not adopt a directly heating method, to improve breakdown or performance degradation of the heater and a locally unbalanced radiant heat of the heater. Thus, a temperature variation of the substrate W may be minimized by a local temperature variation of the main heater 40. Since the main heater 40 is rotatable by the rotation shaft 47, temperature ununiformity of the substrate W may be effectively prevented.

Also, a kanthal heater may be used as the upper and main heaters 27 and 42. Kanthal may be a Fe—Cr—Al alloy, wherein iron is used as a main material. Thus, kanthal may have high heat-resistance and electric-resistance. In addition, since kanthal heating wires of the kanthal heaters are freely modified in shape, radiant heat may be more uniformly distributed and transferred when compared to an existing lamp heating method.

As shown in FIG. 1, the main chamber 10 has an opened lower portion. A hollow pumping block 60 is disposed on the opened lower portion of the main chamber 10. The pumping block 60 is disposed along a circumference of the rotation shaft 47. A discharge hole 62 is defined in the pumping block 60. The discharge hole 62 may be defined along the circumference of the rotation shaft 47. Non-reaction gases or reaction products may be discharged through the discharge hole 62. An exhaust pump 65 is connected to an exhaust port 67 and the discharge hole 62 to forcibly discharge the non-reaction gases or reaction products.

The discharge hole 62 is defined outside the through hole 41. Also, the discharge hole 62 may have a circular ring shape along a circumference of the through hole 41. That is, the gas supply hole 80 and the discharge hole 62 are defined in sides opposite to each other of the substrate processing apparatus 1. Thus, the process gas supplied through an upper side may be discharged toward the discharge hole 62 defined in a lower side to improve flow distribution of the process gas, thereby increasing reactivity.

As described above, the substrate W is transferred into the substrate processing apparatus 1 through a passage 8, and an elevation unit 50 supports the substrate W to elevate the substrate W toward the susceptor plate 30. The elevation unit 50 includes a holder 55 supporting the substrate W and an elevation shaft 53 connected to the holder 55 and elevated together with the holder 55. The transferred substrate W is placed on the holder 55. The elevation shaft 53 is disposed on a lower portion of the holder 55, and an elevation hole 51 is defined in a bottom surface of the main chamber 10. The elevation hole 51 is defined outside the discharge hole 62, and the elevation shaft 53 is inserted along the elevation hole 51. The elevation shaft 53 is connected to a motor 58 and elevated together with the holder 55. As the holder 55 descends toward an elevation groove 35 defined in an edge of a top surface of the susceptor plate 30 to move the substrate W on the susceptor plate 30. Also, the holder 55 may be provided in plurality to stably support the substrate W and transfer the substrate toward the susceptor plate 30.

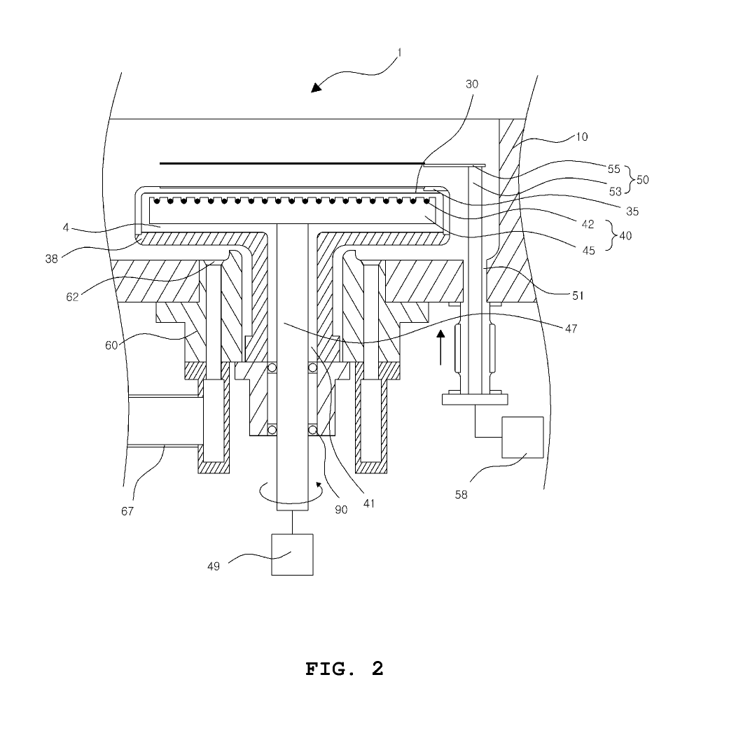

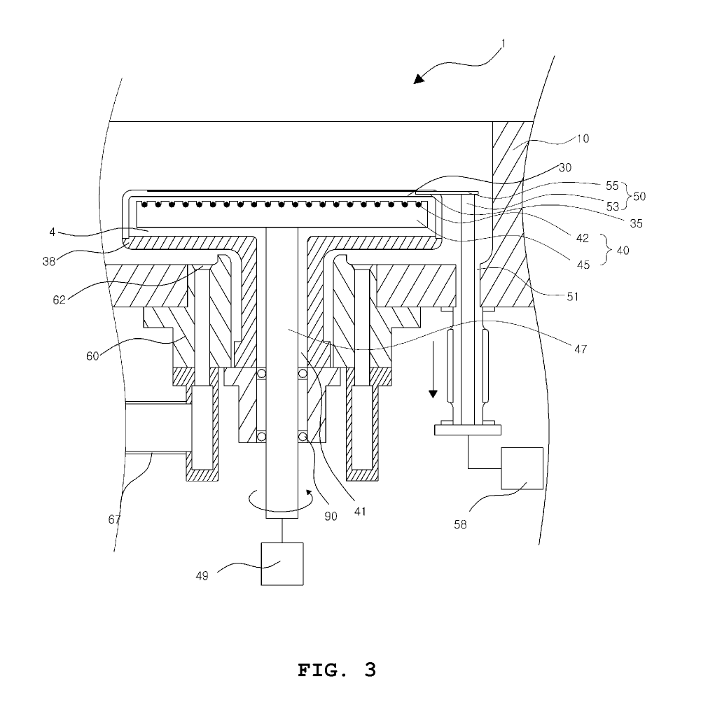

FIGS. 2 and 3 are views illustrating a moving operation of an elevation unit of FIG. 1. Referring to FIGS. 2 and 3, the substrate W transferred into the substrate processing apparatus 1 through the passage 8 is placed on an upper portion of the holder 55. As described above, the elevation shaft 53 is disposed on a lower portion of the holder 55. Also, the elevation shaft 53 is connected to the motor 58 and elevated together with the holder 55. The substrate W transferred on the upper portion of the holder 55 descends toward the susceptor plate 30 as the elevation shaft 53 descends. The holder 55 is seated in the elevation groove 35 of the susceptor plate 30, and then, the substrate W is transferred to a central portion of the susceptor plate 30 to perform a process with respect to the substrate W.

Also, the elevation unit 50 may have an ascending position and a descending position. At the ascending position, the top surface of the holder 55 is higher than that of the susceptor plate 30. Also, at the descending position, the holder 55 is inserted into the elevation groove 35 and spaced apart from a bottom surface of the substrate W to move the substrate W onto the susceptor plate 30.

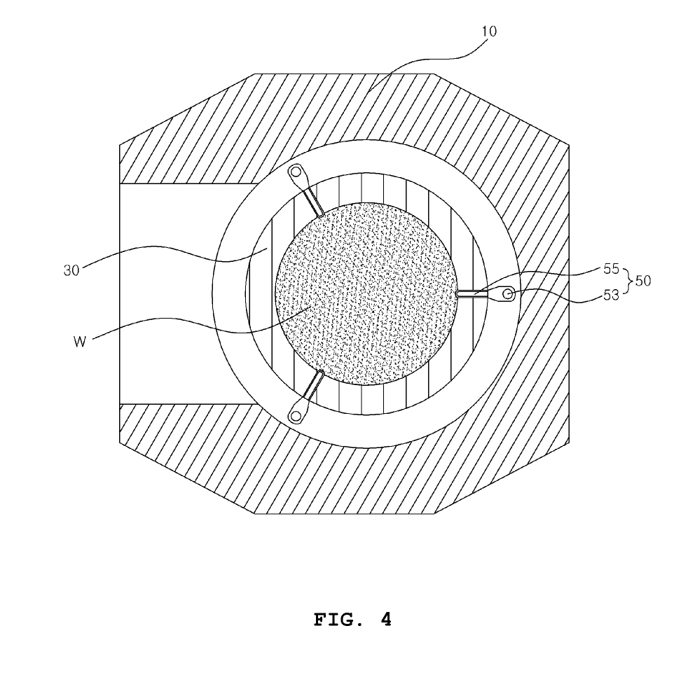

FIG. 4 is a cross-sectional view illustrating an arrangement state of a holder of FIG. 1. Referring to FIG. 4, the holder 55 may be provided in plurality. The plurality of holders 55 may support the substrate W in three directions to transfer the substrate to the susceptor plate 30. The elevation groove 35 of the susceptor plate 30 may be defined with the same number as that of the holder 55. The holders 55 may respectively inserted into the elevation grooves 35 to transfer the substrate W to the central portion of the susceptor plate 30.

Although the present invention is described in detail with reference to the exemplary embodiments, the invention may be embodied in many different forms. Thus, technical idea and scope of claims set forth below are not limited to the preferred embodiments.

### MODE FOR INVENTION

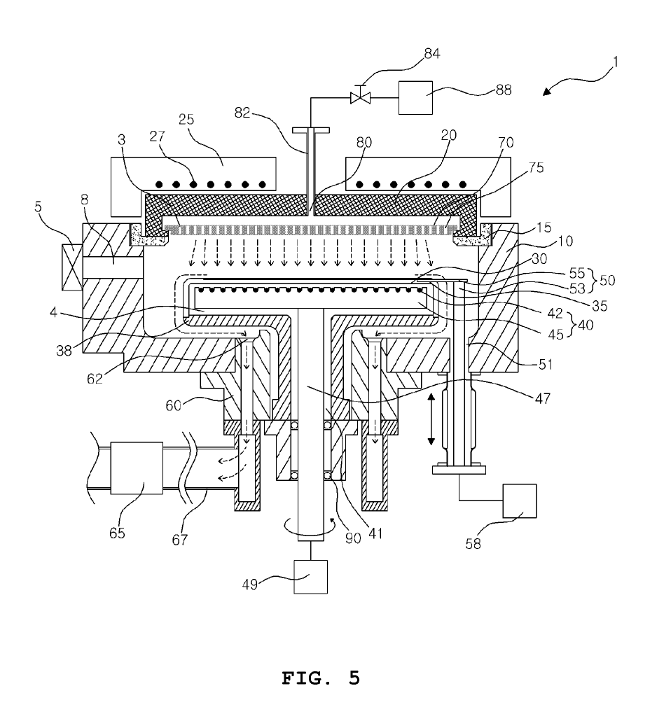

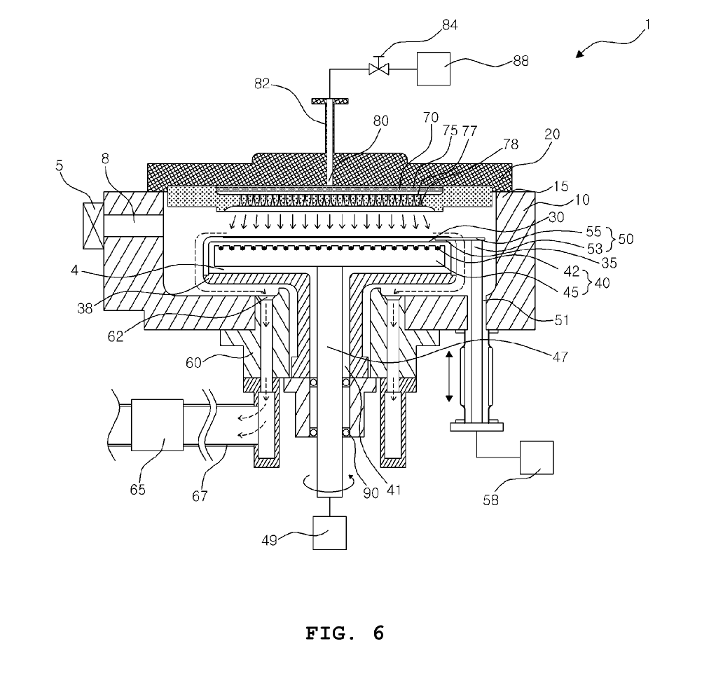

Hereinafter, exemplary embodiments of the present invention will be described in detail with reference to FIGS. 5 to 6. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the shapes of components are exaggerated for clarity of illustration.

FIG. 5 is a schematic view of a substrate processing apparatus according to a first modified example of the present invention. Hereinafter, only features different from those according to the foregoing embodiment will be described. Thus, omitted descriptions herein may be substituted for the above-described contents. Referring to FIG. 5, a chamber cover 20 is disposed on an opened upper portion of a main chamber 10. The chamber cover 20 may have a flat plate shape with an opened lower portion to communicate with the main chamber 10. A connection member 15 completely sealing a space between the chamber cover 20 and the main chamber 10 from an external space may be disposed between the chamber cover 20 and the main chamber 10. A diffusion plate 70 is disposed on a lower end of the chamber cover 20.

Also, the upper heater 25 is disposed above the chamber cover 20 and has a shape corresponding to that of the chamber cover 20. Also, the upper heater 25 is spaced a preset distance from the chamber cover 20. When compared to the foregoing embodiment described with reference to FIG. 1, according to the first modified example, a side portion of the chamber cover 20 may be disposed at a relatively low height to reduce a process space. As a result, reactivity between the substrate W and a process gas may increase to improve a reaction rate of the process gas.

FIG. 6 is a schematic view of a substrate processing apparatus according to a second modified example of the present invention. Referring to FIG. 6, a chamber cover 20 is connected to an upper portion of a main chamber 10. Also, the chamber cover 20 closes an opened upper portion of the main chamber 20 to provide a process space 3 in which a process with respect to a substrate W is performed. A gas supply hole 80 is defined in an upper portion of the chamber cover 20 to supply a process gas into the process space 3. Then, the process gas is sprayed onto the substrate W by spray holes 78 defined in a showerhead 77 disposed under the chamber cover 20. A diffusion plate 70 is disposed between a gas supply hole 80 and the showerhead 77 to primarily diffuse the process gas introduced through the gas supply hole 80 and then flow toward the showerhead 77. The primarily diffused process gas may be re-diffused while passing through the spray holes 78 of the showerhead 77 to flow toward the substrate W. Thus, the second modified example may be effective to form a uniform deposition layer on the substrate W because the process gas is doubly dispersed toward the substrate W in a relative low temperature process.

Although the present invention is described in detail with reference to the exemplary embodiments, the invention may be embodied in many different forms. Thus, technical idea and scope of claims set forth below are not limited to the preferred embodiments.

### INDUSTRIAL APPLICABILITY

The present invention is applicable for a semiconductor manufacturing apparatus and a semiconductor manufacturing method in a various type.

What is claimed is:

1. A substrate processing apparatus in which a process with respect to a substrate is performed, the substrate processing apparatus comprising:
a main chamber having an opened upper portion, the main chamber having a passage that is defined in a sidewall thereof so that a substrate is accessible;
a chamber cover disposed on the opened upper portion of the main chamber to provide a process space, which is sealed from the outside, in which the process is performed;
a susceptor plate on which the substrate is placed, the susceptor plate having an inner space with an opened lower portion; and
a main heater rotatably disposed in the inner space, the main heater being spaced apart from the susceptor plate to heat the susceptor plate.

2. The substrate processing apparatus of claim 1, further comprising a support member disposed on the opened lower portion of the susceptor plate to prevent heat within the inner space from being diffused into the outside.

3. The substrate processing apparatus of claim 2, further comprising a rotation shaft disposed on a lower portion of the main heater to support the main heater, the rotation shaft being rotatable together with the main heater,
wherein the main heater comprises:
a heating plate disposed on an upper portion of the rotation shaft, the heating plate being inserted into the inner space; and
a heating wire disposed in the heating plate to heat the susceptor plate.

4. The substrate processing apparatus of claim 3, wherein the main chamber has an opened lower portion, and
the substrate processing apparatus further comprises a pumping block disposed on the opened lower portion of the main chamber to provide an inner installation space, the pumping block being disposed along a circumference of the rotation shaft.

5. The substrate processing apparatus of claim 4, wherein the main heater and the rotation shaft are disposed in the inner installation space, and
the substrate processing apparatus comprises:
a plurality of holders supporting the substrate placed thereon, the holders being movable between an ascending position and a descending position;
an elevation shaft connected to the holders to elevate the holders;
a discharge hole defined in the pumping block along the circumference of the rotation shaft to discharge a process gas to the outside; and
an elevation hole in which the elevation shaft is inserted, the elevation hole being defined outside the discharge hole.

6. The substrate processing apparatus of claim 1, further comprising:
a gas supply hole defined in a top surface of the chamber cover to supply the process gas into a process space;
a diffusion plate disposed on a lower end of the chamber cover, the diffusion plate having diffusion holes through which the process gas is diffused onto the substrate; and
an upper heater disposed on an upper portion of the chamber cover to preliminarily heat the process gas to be supplied into the process space.

7. The substrate processing apparatus of claim 1, further comprising an elevation unit elevating the substrate,
wherein the elevation unit comprises:
a plurality of holders supporting the substrate placed thereon, the holders being movable between an ascending position and a descending position; and
an elevation shaft connected to the holders to elevate the holders.

8. The substrate processing apparatus of claim 7, wherein the susceptor plate has an elevation groove defined along an edge of a top surface thereof, and
each of the holders has a top surface having a height greater than that of a top surface of the susceptor plate at the ascending position and is inserted into the elevation groove and spaced apart from a bottom surface of the substrate at the descending position.

9. The substrate processing apparatus of claim 1, wherein the chamber cover has an upper portion with a dome shape that protrudes upward or a flat plate shape.
